(19) United States
(12) Patent Application Publication
(10) Pub. No.: US 2012/0104438 A1
(43) Pub. Date: May 3, 2012

(54) LIGHT EMITTING DIODE PACKAGE STRUCTURE

(75) Inventors: KAI-LUN WANG, Hukou (TW); SHIH-YUAN HSU, Hukou (TW)

(73) Assignee: ADVANCED OPTOELECTRONIC TECHNOLOGY, INC., Hsinchu Hsien (TW)

(21) Appl. No.: 13/172,738

(22) Filed: Jun. 29, 2011

(30) Foreign Application Priority Data
Oct. 28, 2010 (CN) 201010523441.1

(51) Int. Cl. H01L 33/60

(52) U.S. Cl. 257/98; 257/E33.061

(57) ABSTRACT

An LED package structure includes a substrate, a first electrical portion and a second electrical portion formed on the substrate, and an LED chip mounted on a first surface of the first electrical portion. The first and second electrical portions are electrically insulated from each other. The LED chip includes a first electrode connected with the first electrical portion and a second electrode connected with the second electrical portion through a connecting wire. The LED chip has a top surface for supporting the second electrode. The connecting wire has a highest point. A distance between the highest point and the top surface is less than a half of a distance between the first surface of the first electrical portion and the top surface of the LED chip.

### TECHNICAL FIELD

The disclosure generally relates to a light emitting diode package structure.

### DESCRIPTION OF RELATED ART

In recent years, due to excellent light quality and high luminous efficiency, light emitting diodes (LEDs) have increasingly been used to substitute for incandescent bulbs or compact fluorescent lamps or fluorescent tubes as a light source of an illumination device.

In a conventional LED package structure, wire bonding technique is often used to provide interconnection between an LED chip and a lead frame. However, during conventional wire bonding technique, a connecting wire is usually too long, and increases a cost of the LED package structure.

Therefore, an LED package structure is desired to overcome the above described shortcomings.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a cross-sectional view of an LED package structure in accordance with a first embodiment of the present disclosure.

FIG. 2 is a cross-sectional view of an LED package structure in accordance with a second embodiment of the present disclosure.

FIG. 3 is a cross-sectional view of an LED package structure in accordance with a third embodiment of the present disclosure.

FIG. 4 is a cross-sectional view of an LED package structure in accordance with a fourth embodiment of the present disclosure.

FIG. 5 is a cross-sectional view of an LED package structure in accordance with a fifth embodiment of the present disclosure.

### DETAILED DESCRIPTION

Embodiments of an LED package structure will now be described in detail below and with reference to the drawings.

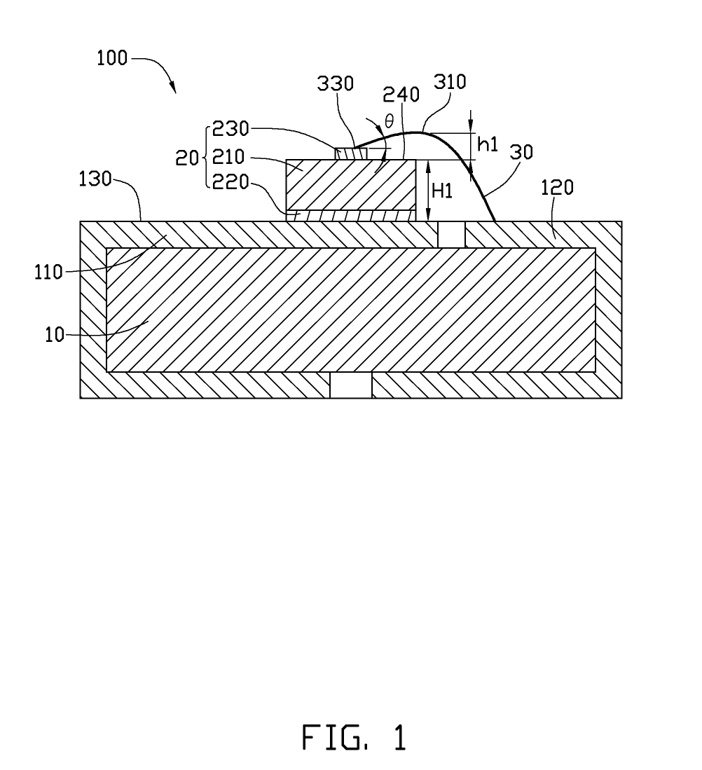

Referring to FIG. 1, an LED package structure 100 in accordance with a first embodiment includes a substrate 10, an LED chip 20 arranged on the substrate 10 and a connecting wire 30.

The substrate 10 can be an Al-based circuit board or a ceramic substrate with conductive circuits. The ceramic substrate can be selected from a group consisting of Al₂O₃ substrate, ZnO substrate and silicon substrate. A first electrical portion 110 and a second electrical portion 120 are formed on a surface of the substrate 10. The first electrical portion 110 is separated and electrically insulated from the second electrical portion 120. In this embodiment, the first electrical portion 110 and the second electrical portion 120 extend along an upper surface of the substrate 10 to a bottom surface of the substrate 10. The first electrical portion 110 has a first surface 130 away from the bottom surface of the substrate 10. The first surface 130 is configured to support the LED chip 20.

The LED chip 20 is mounted on the first surface 130 of the first electrical portion 110. The LED chip 20 includes a semiconductor lighting structure 210, and a first electrode 220 and a second electrode 230 formed on two opposite surfaces of the semiconductor lighting structure 210. In this embodiment, the first electrode 220 is formed at the bottom surface of the LED chip 20 and is electrically connected with the first surface 130 of the first electrical portion 110 by soldering or wafer bonding. Therefore the LED chip 20 is secured at the first surface 130 of the first electrical portion 110. The LED chip 20 further includes a top surface 240 away from the first surface 130 of the first electrical portion 110. The second electrode 230 is formed on the top surface 240 of the LED chip 20.

The connecting wire 30 is configured to form an electrical connection between the second electrode 230 and the second electrical portion 120. The connecting wire 30 can be made of gold. The connecting wire 30 has a highest point 310. The highest point is a point of the connecting wire 30 farthest away from the first surface 130 of the first electrical portion 110. The highest point 310 satisfies the following condition: h₁<H₁/2, wherein h₁ represents the distance between the highest point 310 and the top surface 240 of the chip 20; and H₁ represents a distance between the top surface 240 and the first surface 130 of the first electrical portion 110. Because the distance h₁ between the highest point 310 and the top surface 240 is less than half of the distance H₁ between the second surface 240 and the first surface 130, a height of the connecting wire 30 can be efficiently reduced, and accordingly, the length of the connecting wire 30 can be efficiently reduced. Therefore, a cost and a thickness of the LED package structure 100 are decreased.

The connecting wire 30 has a connecting end 330 secured to the second electrode 230 of the chip 20. An included angle θ formed between a tangent line of the connecting wire 30 at the connecting end 330 and the top surface 240 ranges from 0 degree to 45 degrees. Preferably, the included angle 0 does not exceed 30 degrees to reduce the stress in the wire bonding between the connecting wire 30 and the second electrode 230. The length of the connecting wire 30 can be reduced by decreasing the included angle θ, and accordingly, the cost of the LED package structure 100 can be decreased.

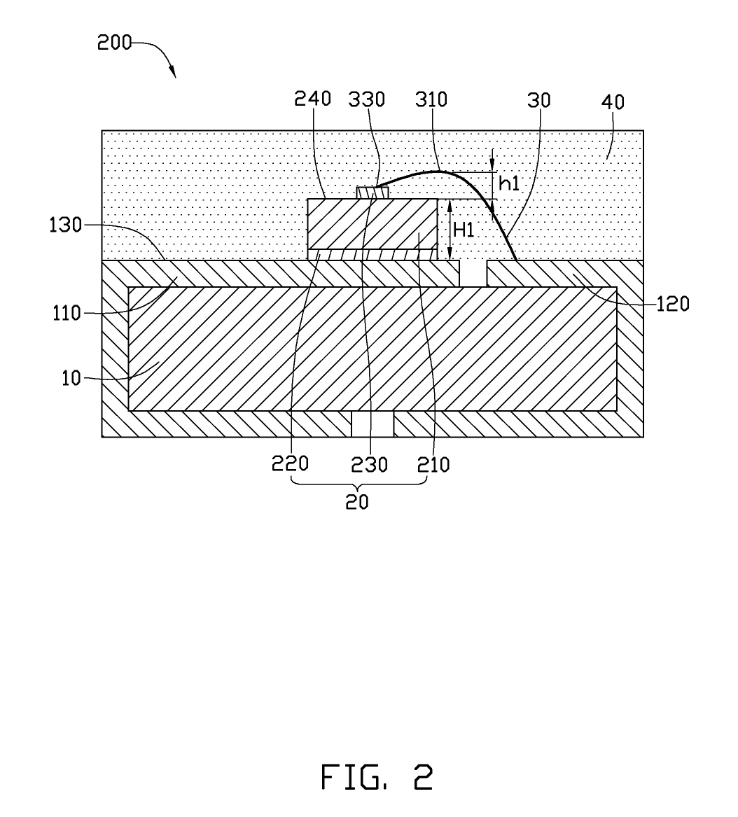

As shown in FIG. 2, an LED package structure 200 in accordance with a second embodiment is shown. In this embodiment, the LED package structure 200 further includes a package material 40 covering the LED chip 20 and the connecting wire 30 for preventing the LED chip 20 from being affected by the outer environment such as moisture or dust. In this embodiment, the package material 40 can be epoxy resin, silicone or glass. The package material 40 can also be doped with phosphor particles whereby the LED package structure 200 can emit light with a desired color, for example, white light.

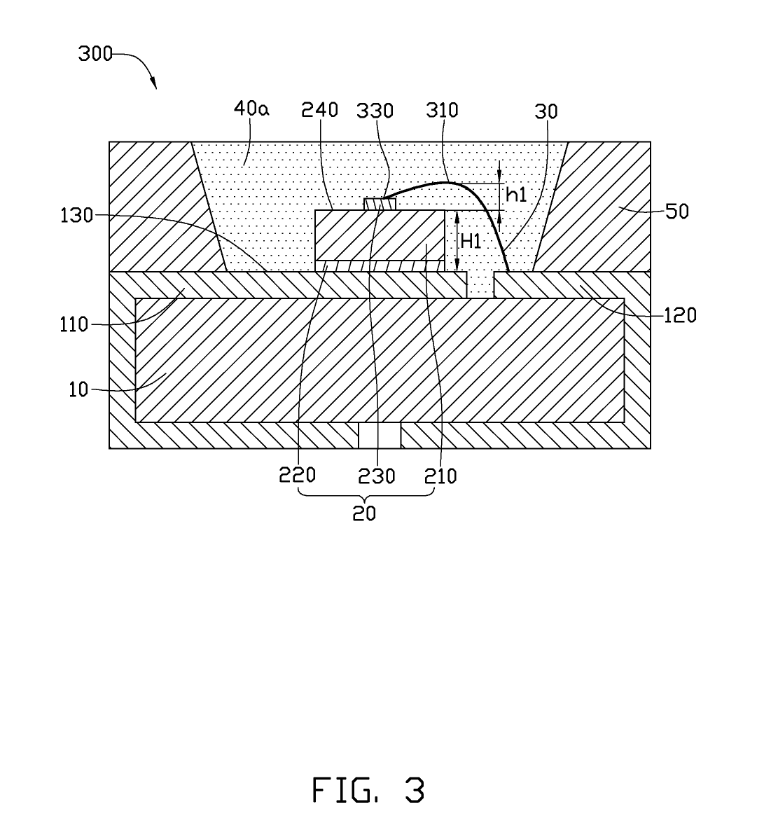

Referring to FIG. 3, differing from the first embodiment, an LED package structure 300 according to a third embodiment further includes a reflective cup 50 and a packing material 40a. The reflective cup 50 is arranged on the first and second electrical portions 110, 120, and surrounds the LED chip 20. The reflective cup 50 and the substrate 10 together form a receiving cavity. The LED chip 20 is positioned inside the receiving cavity, and the light emitted from the LED chip 20 illuminating to the reflective cup 50 will be reflected by an inner wall of the reflective cup 50. In this embodiment, the package material 40a is filled in the receiving cavity and covers the LED chip 20 and the connecting wire 30 completely. Similarly, the package material 40a can be doped with phosphor particles for converting the light from the LED chip 20 to a light with a required, for example, longer, wavelength.

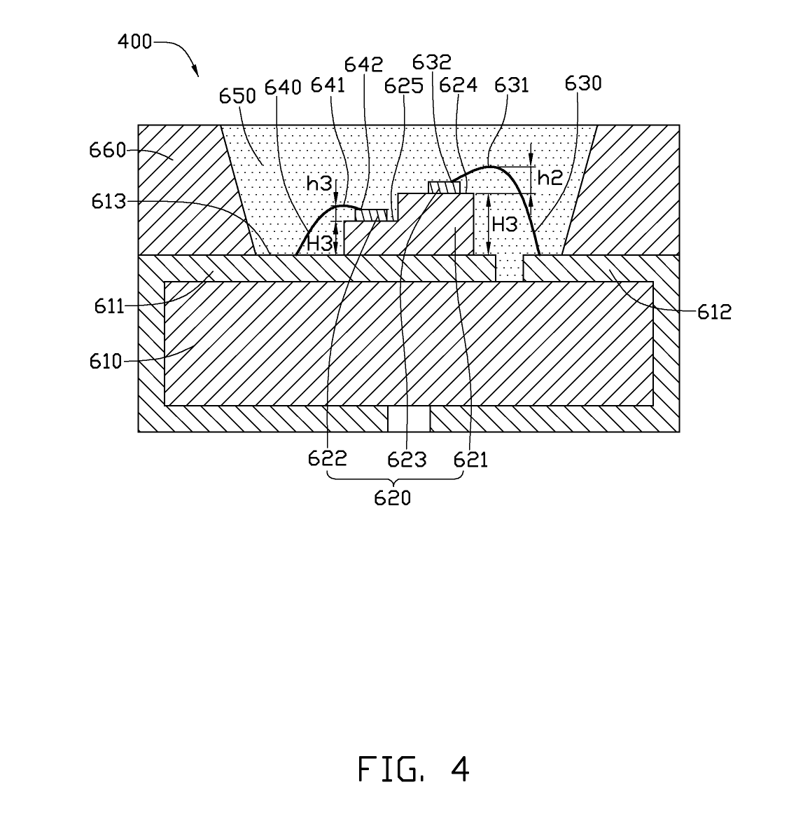

Referring to FIG. 4, an LED package structure 400 in accordance with a fourth embodiment includes a substrate 610, an LED chip 620 formed on a surface of the substrate 610, a first connecting wire 630, a second connecting wire 640, a package material 650 and a reflective cup 660. In this embodiment, the LED chip 620 has a first electrode 622 and a second electrode 623 both formed on a top side thereof.

A first electrical portion 611 and a second electrical portion 612 are formed on a surface of the substrate 610. The first electrical portion 611 and the second electrical portion 612 are extending from an upper surface of substrate 610 to a bottom surface of the substrate 610. The first electrical portion 611 is electrically insulated from the second electrical portion 612. The first electrical portion 611 has a first surface 613 for supporting the LED chip 620.

The LED chip 620 includes a semiconductor lighting structure 621, the first electrode 622 and the second electrode 623. The top side of the semiconductor lighting structure 621 is step-shaped, and has an upper surface 624 and a lower surface 625 parallel to and lower than the upper surface 624. The second electrode 623 is formed on the upper surface 624 and the first electrode 622 is formed on the lower surface 625. The second electrode 623 is electrically connected with the second electrical portion 612 by a first connecting wire 630. The first connecting wire 630 has a highest point 631. The highest point 631 is a point of the first connecting wire 630 farthest away from the first surface 613. The highest point 631 satisfies the following condition: h₂<H₂/2, wherein h₂ represents a distance between the highest point 631 and the upper surface 624; and H₂ represents a distance between the upper surface 624 and the first surface 613. In this embodiment, the LED chip 620 is secured on the first surface 613 of the first electrical portion 611 by glue. A second connecting wire 640 is configured to electrically connect the first electrode 622 with the first electrical portion 611. The second connecting wire 640 has a highest point 641. The highest point 641 is a point of the second connecting wire 640 farthest away from the first surface 613. The highest point 641 satisfies the following condition: h₃<H₃/2, wherein h₃ represents a distance between the highest point 641 and the lower surface 625; and H₃ represents a distance between the lower surface 625 and the first surface 613.

The first connecting wire 630 has a first connecting point 632 connected to the second electrode 623. An included angle θ formed between a tangent line of the first connecting wire at the first connecting point 632 and the upper surface 624 is in a range from 0 degree to 45 degrees for reducing the probability of break of the first connecting wire 630 from the second electrode 623. Preferably, the included angle θ is between 0 degree and 30 degrees.

The LED package structure 600 further includes the package material 650. The package material 650 covers the LED chip 620, the first connecting wire 630 and the second connecting wire 640 for preventing the LED chip 620 from being affected by the outer environment such as moisture or dust. In this embodiment, the package material 650 can be epoxy resin, silicone or glass. And, the package material 650 can be doped with phosphor particles for converting the light from the LED chip 620 to a light with a required, for example, longer, wavelength.

The LED package structure 600 further includes the reflective cup 660. The reflective cup 660 surrounds the LED chip 620 and is formed on the substrate 610. The reflective cup 660 and the substrate 610 together form a receiving cavity. The LED chip 620 is positioned inside the receiving cavity, and the light emitted from the LED chip 620 to the reflective cup 660 is reflected by an inner wall of the reflective cup 660. In this embodiment, the package material 650 is formed inside the receiving cavity and totally covers the LED chip 620, the first connecting wire 630 and the second connecting wire 640. Similarly, the package material 650 can be doped with phosphor particles for converting the light from the LED chip 620 to a light with a desired, for example, longer, wavelength.

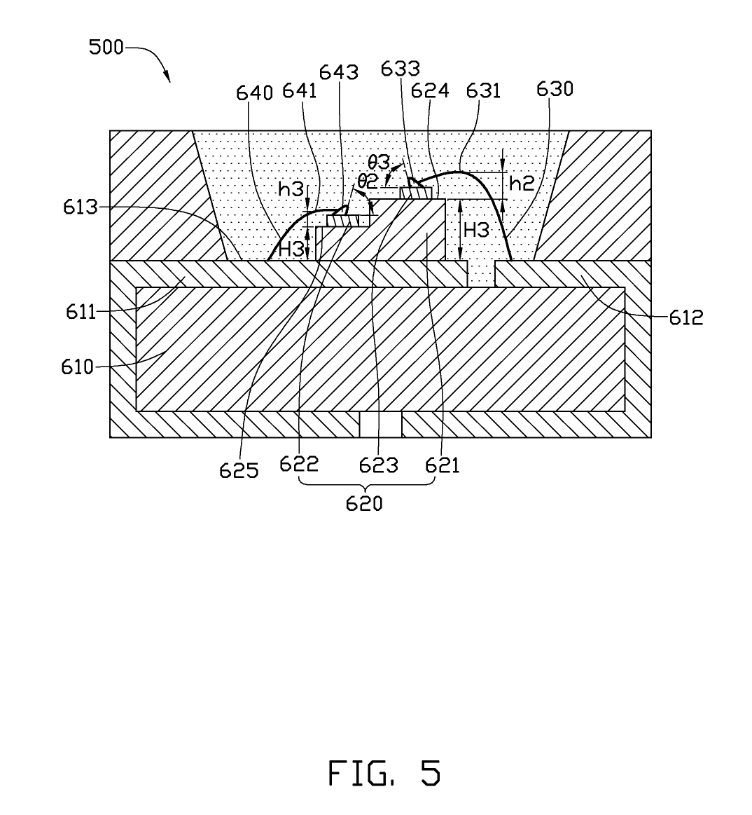

Referring to FIG. 5, an LED package structure 500 according to a fifth embodiment is shown. Different from the LED package structure 400 of the fourth embodiment, a solder slug 633 is formed at one end of the first connecting wire 630 adjacent to the second electrode 623. The solder slug 633 is configured to enhance electrical connection performance between the first connecting wire 630 and the second electrode 623. In this embodiment, the solder slug 633 forms an included angle θ3 with the second electrode 623. The included angle θ3 is between 0 degree and 90 degrees. Preferably, the included angle θ3 is between 0 degree and 45 degrees for reducing the probability of break of the first connecting wire 630 from the second electrode 623.

Similarly, a second solder slug 643 is formed at one end of the second connecting wire 640 adjacent to the first electrode 622. The second solder slug 643 forms an included angle θ2 with the first electrode 622 for reducing the probability of break of the second connecting wire 640 from the first electrode 622.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An LED package structure, comprising:
a substrate;
a first electrical portion and a second electrical portion formed on the substrate, the first electrical portion being electrically insulated from the second electrical portion, the first electrical portion having a top surface; and
an LED chip being mounted on the top surface of the first electrical portion, the LED chip comprising:
a first electrode electrically connected to the first electrical portion,
a second electrode formed on a top surface of the LED chip, and
a connecting wire connecting the second electrode with the second electrical portion, the connecting wire having a highest point farthest away from the substrate, a distance between the highest point and the top surface of the LED chip is less than a half of a distance between the top surface of the LED chip and the top surface of the first electrical portion.

2. The LED package structure of claim 1, wherein the first electrical portion and the second electrical portion extend from an upper surface of the substrate to a bottom surface of the substrate.

3. The LED package structure of claim 1, wherein a connecting point is formed between the connecting wire and the second electrode, an included angle between a tangent line of the connecting wire at the connecting point and the top surface of the LED chip ranges from 0 degree to 45 degrees.

4. The LED package structure of claim 3, wherein the included angle ranges from 0 degree to 30 degrees.

5. The LED package structure of claim 1, further comprising a package material covering the LED chip and the connecting wire.

6. The LED package structure of claim 5, wherein the package material is doped with phosphor particles.

7. The LED package structure of claim 1, further comprising a reflective cup, the reflective cup and the substrate together forming a receiving cavity, the LED chip being received inside the receiving cavity.

8. The LED package structure of claim 7, wherein the receiving cavity is filled with a package material, the package material covering the LED chip and the connecting wire.

9. The LED package structure of claim 1, wherein a solder slug is formed on the second electrode, and the connecting wire is connected to the solder slug.

10. The LED package structure of claim 1, wherein the first electrode is formed at a bottom side of the LED chip, and is connected to the first electrical portion directly.

11. The LED package structure of claim 1, wherein the first electrode is formed on the top surface of the LED chip, and is connected to the first electrical portion by another connecting wire.

12. The LED package structure of claim 11, wherein the top surface is step-shaped and includes an upper portion and a lower portion, the second and first electrodes are respectively formed on the upper and lower portions.

13. The LED package structure of claim 12, wherein the another connecting wire has a highest point farthest away from the substrate, a distance between the highest point of the another connecting wire and the lower portion of the top surface of the LED chip is less than a half of a distance between the lower portion of the top surface of the LED chip and the top surface of the first electrical portion.

14. The LED package structure of claim 13, wherein another connecting point is formed between the another connecting wire and the first electrode, an included angle between a tangent line of the another connecting wire at the another connecting point and the lower portion of the top surface of the LED chip ranges from 0 degree to 45 degrees.
